(19) United States
(12) Patent Application Publication
(10) Pub. No.: US 2016/0172443 A1
(43) Pub. Date: Jun. 16, 2016

(54) METHOD AND APPARATUS TO TUNE THRESHOLD VOLTAGE OF DEVICE WITH HIGH ANGLE SOURCE/DRAIN IMPLANTS

(71) Applicant: Texas Instruments Incorporated, Dallas, TX (US)

(72) Inventors: Younsung Choi, Allen, TX (US); Kwan-Yong Lim, Plano, TX (US); Seung-Chul Song, Plano, TX (US); Song Zhao, Plano, TX (US)

(21) Appl. No.: 14/967,199

(22) Filed: Dec. 11, 2015

Related U.S. Application Data
(60) Provisional application No. 62/091,425, filed on Dec. 12, 2014.

(51) Int. Cl. H01L 29/08; H01L 29/66; H01L 29/78; H01L 29/49

(52) U.S. Cl. CPC H01L 29/0847; H01L 29/4916; H01L 29/66492; H01L 29/7836

(57) ABSTRACT

A method for tuning a threshold voltage of a semiconductor device includes implanting at least one dopant in a semiconductor substrate at an angle to form a source region and/or a drain region of a transistor. The angle is oblique to a surface of the substrate. Implanting the at least one dopant at the angle alters a flat-band voltage of the transistor and shifts the threshold voltage of the transistor. The at least one dopant or at least one additional dopant can be implanted in a gate electrical contact of the transistor. Implanting the at least one dopant at the oblique angle can change an electrostatic potential of a gate electrical contact of the transistor compared to implanting the at least one dopant at a non-oblique angle, and the change in the electrostatic potential of the gate electrical contact can shift the threshold voltage of the transistor.

### CROSS-REFERENCE TO RELATED APPLICATION AND PRIORITY CLAIM

This application claims priority under 35 U.S.C. §119(e) to U.S. Provisional Patent Application No. 62/091,425 filed on Dec. 12, 2014. This provisional application is hereby incorporated by reference in its entirety.

### TECHNICAL FIELD

This disclosure is generally directed to integrated circuits. More specifically, this disclosure is directed to a method and apparatus to tune a threshold voltage of a device with high angle source/drain implants.

### BACKGROUND

Transistors are widely used in the electronics industry for switching, amplification, filtering, and other tasks related to both analog and digital electrical signals. One common type of transistor is a metal oxide semiconductor field effect transistor (MOSFET). In a MOSFET, a channel region allows electrons to travel between a source region and a drain region of a semiconductor substrate, and a gate electrode is used to control the flow of electrons through the channel region. The source and drain regions are typically formed by adding one or more dopants to targeted regions of the semiconductor substrate on either side of the channel region.

### SUMMARY

This disclosure provides a method and apparatus to tune a threshold voltage of a device with high angle source/drain implants.

In a first example embodiment, a method for tuning a threshold voltage of a semiconductor device includes implanting at least one dopant in a semiconductor substrate at an angle to form at least one of a source region and a drain region of a transistor. The angle is oblique to a surface of the substrate. Implanting the at least one dopant at the angle alters a flat-band voltage of the transistor and shifts the threshold voltage of the transistor.

In a second example embodiment, a method of forming a transistor includes obtaining a semiconductor substrate and forming a gate structure over the semiconductor substrate. The gate structure includes a gate electrical contact and a gate dielectric layer disposed between the semiconductor substrate and the gate electrical contact. The method also includes implanting at least one dopant in the semiconductor substrate at an angle to form at least one of a source region and a drain region of the transistor. The angle is oblique to a surface of the semiconductor substrate.

In a third example embodiment, a transistor includes a semiconductor substrate and a gate structure over the semiconductor substrate. The gate structure includes a gate electrical contact and a gate dielectric layer disposed between the semiconductor substrate and the gate electrical contact. The transistor also includes a source region and a drain region in the semiconductor substrate. At least one of the source and drain regions includes at least one dopant implanted in the semiconductor substrate at an angle that is oblique to a surface of the semiconductor substrate.

Other technical features may be readily apparent to one skilled in the art from the following figures, descriptions, and claims.

### BRIEF DESCRIPTION OF THE DRAWINGS

For a more complete understanding of this disclosure and its features, reference is now made to the following description, taken in conjunction with the accompanying drawings, in which:

FIG. 1 illustrates a cross-sectional view of an example semiconductor device according to this disclosure;

FIGS. 2 through 6 illustrate charts showing example characteristics associated with tuning a threshold voltage of a semiconductor device according to this disclosure; and

FIG. 7 illustrates an example method for fabricating a semiconductor device according to this disclosure.

### DETAILED DESCRIPTION

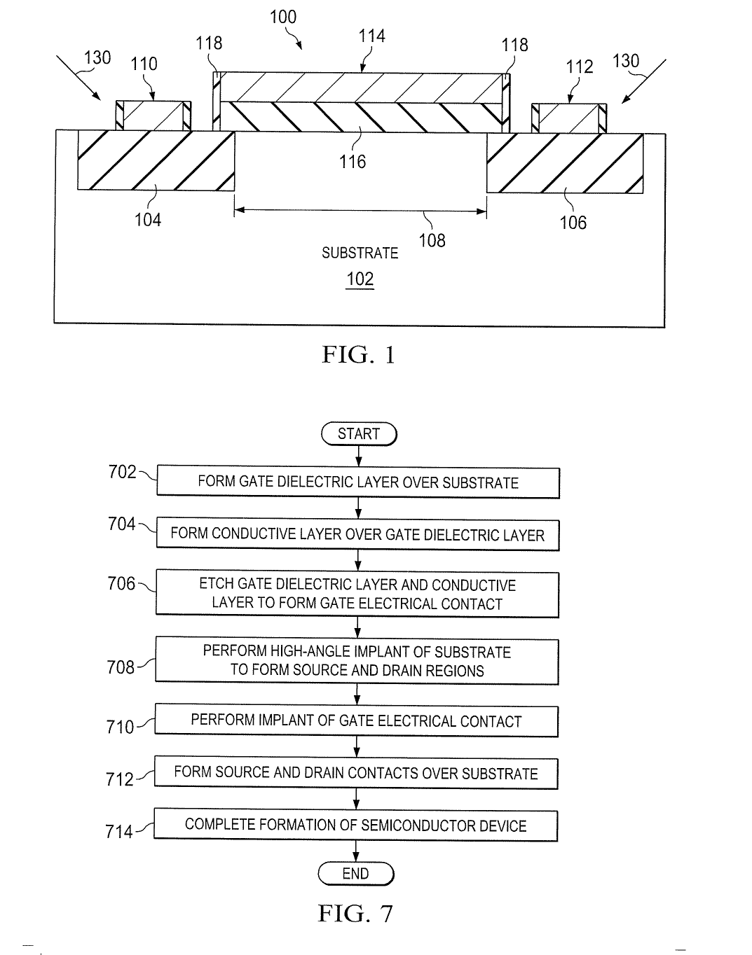

FIGS. 1 through 7, discussed below, and the various embodiments used to describe the principles of this disclosure in this patent document are by way of illustration only and should not be construed in any way to limit the scope of the disclosure. Those skilled in the art will understand that the principles of this disclosure may be implemented in any suitable manner and in any type of suitably arranged device or system.

FIG. 1 illustrates a cross-sectional view of an example semiconductor device 100 according to this disclosure. As shown in FIG. 1, the semiconductor device 100 includes a semiconductor substrate 102. The semiconductor substrate 102 represents any suitable substrate in or on which other components of a semiconductor device can be fabricated, such as a p-type or n-type substrate. The semiconductor substrate 102 could, for example, represent a silicon substrate.

Two wells 104-106 are separated by a channel region 108 in the semiconductor substrate 102. The well 104 defines a source region of a transistor, and the well 106 defines a drain region of the transistor. The channel region 108 defines a region where electrons can flow between the source and drain regions of the transistor. Each well 104-106 could have any suitable size, shape, and dimensions. Each well 104-106 could also be formed in any suitable manner. For instance, each well 104-106 could be implanted with n-type dopant(s) in an NMOS device or with p-type dopant(s) in a PMOS device. The channel region 108 could have any suitable size, shape, and dimensions.

A source contact 110, a drain contact 112, and a gate contact 114 provide electrical connections to the semiconductor device 100. Each contact 110-114 could be formed from any suitable material(s) and in any suitable manner. For example, each contact 110-114 could be formed by depositing and etching one or more conductive materials, such as polysilicon. Each contact 110-114 could also have any suitable size, shape, and dimensions. Note that an optional bulk contact (not shown) could provide electrical connection to the semiconductor substrate 102.

A gate dielectric 116 is located between the gate contact 114 and the underlying substrate 102, and sidewall spacers 118 are disposed along edges of various structures in FIG. 1. The gate dielectric 116 and the sidewall spacers 118 could be formed from any suitable material(s) and in any suitable manner. For example, the gate dielectric 116 and the sidewall spacers 118 could be formed from oxide. As a particular example, the gate dielectric 116 could be formed from silicon oxynitride (SiON) or silicon dioxide (SiO₂). Each of the gate dielectric 116 and the sidewall spacers 118 could also have any suitable size, shape, and dimensions.

Note that FIG. 1 illustrates a simplified example of a transistor and that additional components could be added to FIG. 1 in various implementations. For example, a p-type well could be provided in the substrate 102 for a bulk contact in an NMOS transistor, or an n-type well could be provided in the substrate 102 for a bulk contact in a PMOS transistor. As another example, in a PMOS transistor, the p-type wells 104-106, the channel region 108, and the n-type well for the bulk contact could be located within a larger n-well within the substrate 102. Various transistor designs can have different arrangements of wells and other structures within or over the substrate 102.

A threshold voltage (Vₜ) denotes the gate-to-source voltage value needed to render the channel region 108 conductive between the source and drain regions (wells 104-106) of the semiconductor device 100. The threshold voltage of a transistor is typically dependent upon the flat-band voltage of the transistor, and the flat-band voltage typically depends on the difference between the gate work function and the semiconductor work function of the transistor. The work function of a material is a measure of the voltage or energy needed to move an electron in the material outside of a material atom from the Fermi level. The work function is usually expressed in electron volts (eV).

For CMOS products, it is often necessary or desirable to provide predictable, repeatable, and stable threshold voltages for NMOS and PMOS transistors. A conventional method of tuning the threshold voltage of a transistor is to implant dopant directly under a channel region or by diffusing dopant into the substrate under the channel region.

In accordance with this disclosure, the implantation of dopant(s) into the source and drain regions occurs at a high angle 130, such as about 45°. The angle here is oblique with respect to the substrate 102, meaning the angle is not perpendicular to a surface of the substrate 102. The dopant(s) can also be implanted into the gate contact 114. Here, threshold voltage tuning is not due to poly depletion effects or defective charges in the gate oxide. Rather, this approach alters the flat-band voltage of the semiconductor device 100, thereby shifting the threshold voltage of the semiconductor device 100.

Although FIG. 1 illustrates a cross-sectional view of one example of a semiconductor device 100, various changes may be made to FIG. 1. For example, the high-angle implant is shown here as affecting both the source and drain regions, although the high-angle implant could be used with only one of these regions. Also, multiple high-angle implants could be performed on different regions of the substrate 102, where other regions of the substrate 102 are appropriately masked.

FIGS. 2 through 6 illustrate charts showing example characteristics associated with tuning a threshold voltage of a semiconductor device 100 according to this disclosure. FIG. 2 illustrates an example energy band diagram 200 that includes a diagram 202 showing a flat-band voltage without high angle source/drain implants and a diagram 204 showing a flat-band voltage with high angle source/drain implants. The diagrams 202 and 204 plot various key electron energy levels (Fermi levels and nearby energy band edges) as a function of a spatial dimension. The vertical axes of the band diagrams represent the energy of an electron, which includes both kinetic and potential energy. The horizontal axes of the band diagrams represent position and are not drawn to scale. The symbol “φ” represents electrostatic potential.

In diagram 202, φₘ 212 denotes an electrostatic potential of an N+ poly gate 206, and φₛ 214 denotes an electrostatic potential of a P− substrate 210. The gate 206 and the substrate 210 are separated by a dielectric layer 208, such as a layer of SiON. Also, φₘₛ 216 denotes a work function difference between the gate 206 and the substrate 210. As noted above, the device associated with the diagram 202 does not include high angle source/drain implants.

In diagram 204, φₘ′ 220 denotes the value of φₘ 212 from the diagram 202, φₘ 222 denotes an electrostatic potential of an N+ poly gate 206′, and φₛ 224 denotes an electrostatic potential of a P− substrate 210′. The gate 206′ and the substrate 210′ are separated by a dielectric layer 208′, such as a layer of SiON. Also, φₘₛ 226 denotes a work function difference between the gate 206′ and the substrate 210′. As noted above, the device associated with the diagram 204 does include high angle source/drain implants.

As can be seen in FIG. 2, due to the use of a high angle implant of the source region and/or drain region of a transistor, the work function difference is reduced from φₘₛ 216 to φₘₛ 226. This approach can therefore be used to alter the flat-band voltage of a semiconductor device since the flat-band voltage V_{fb} depends on the value of φₘₛ.

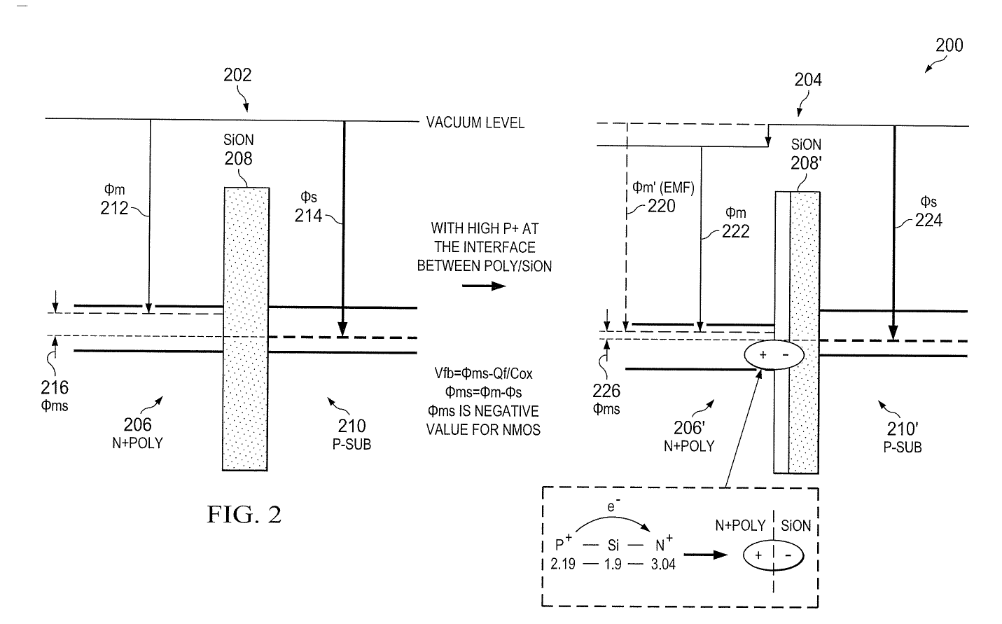

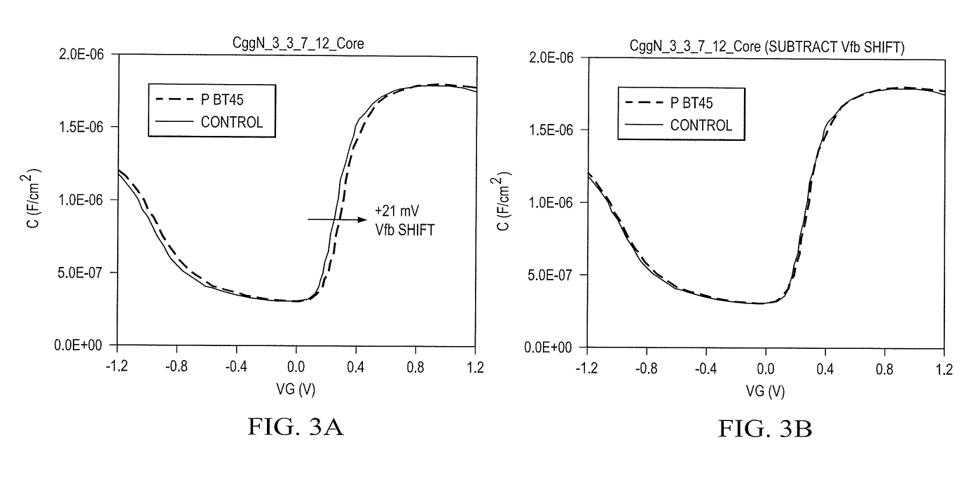

FIGS. 3A and 3B illustrate example capacitance-voltage (C-V) curves of a conventional device and the semiconductor device 100. As shown in FIG. 3A, the C-V curves of the conventional device and the semiconductor device 100 differ. In this particular example, the difference is associated with a shift in the flat-band voltage V_{fb} of the semiconductor device 100 of about +21 mV, although other amounts of shift could occur. However, in FIG. 3B, the C-V curves of the conventional device and the semiconductor device 100 actually overlap almost perfectly once the shift in the flat-band voltage V_{fb} of the semiconductor device 100 is disregarded.

The flat-band voltage shift observed here can be explained by dipole formation at the interface of the gate contact 114 and the gate dielectric 116 (such as a polysilicon-SiON interface). This dipole formation lowers φₘₛ, which represents the work function difference between the gate contact 114 and the semiconductor substrate 102. As a result, both the flat-band voltage V_{fb} and the threshold voltage Vₜ of the semiconductor device 100 are shifted in a more positive direction, which results in a higher threshold voltage in the semiconductor device 100.

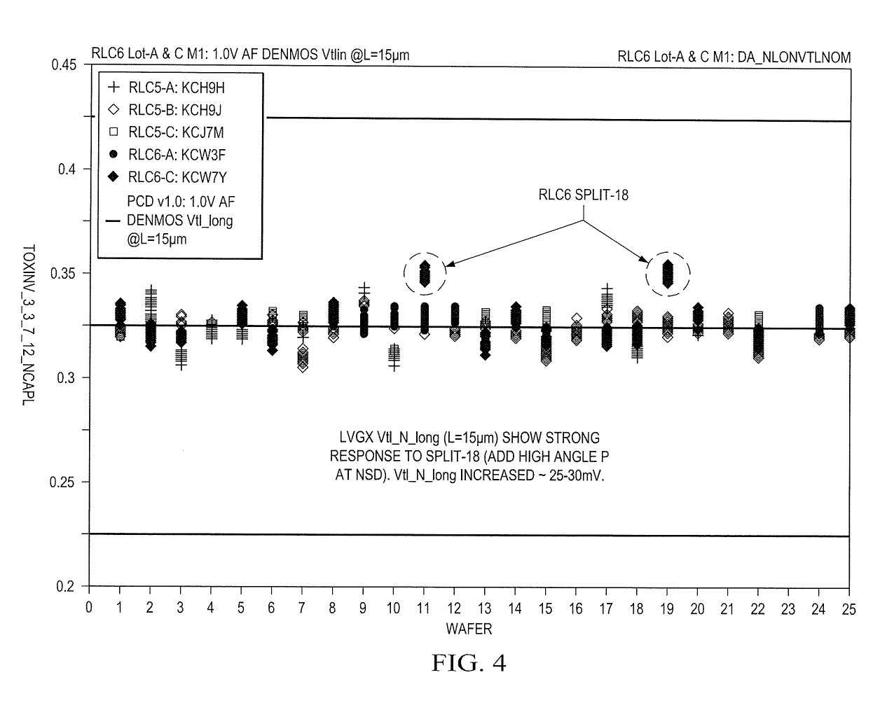

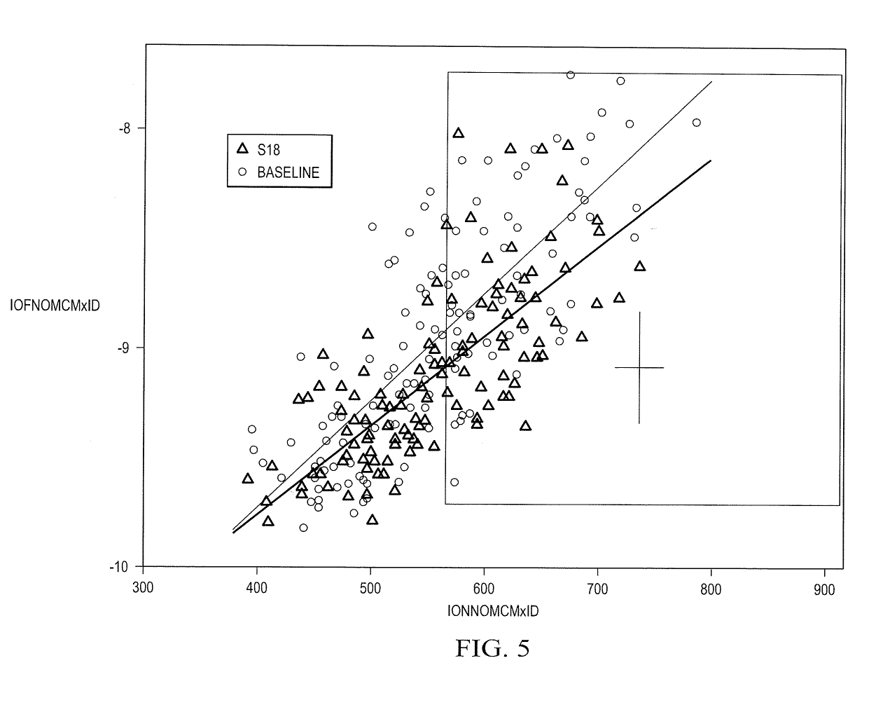

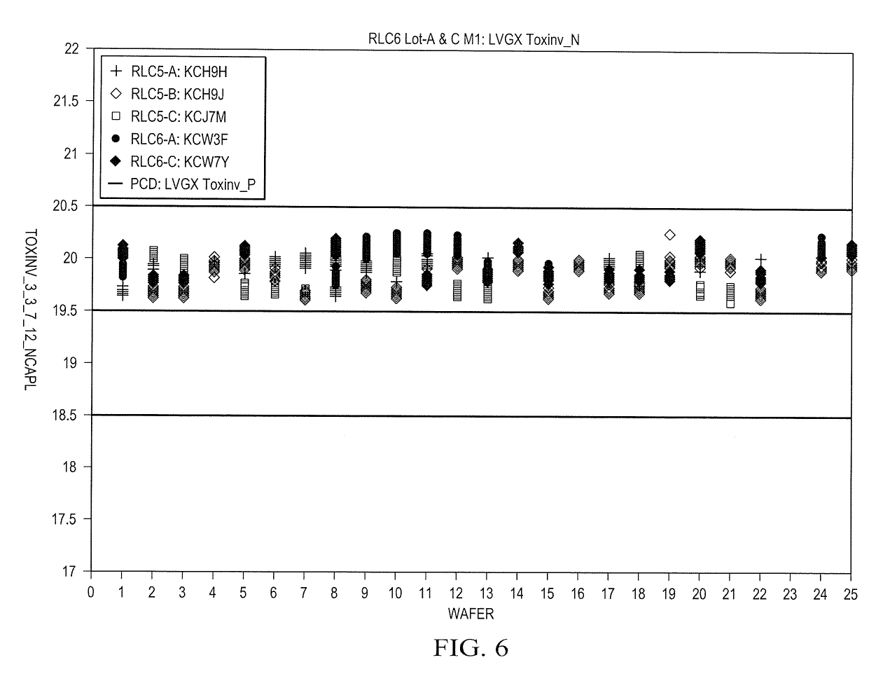

FIG. 4 illustrates example systematic threshold voltage shifts in long-channel devices. FIG. 5 illustrates that comparable or better logic performance can be obtained using a high-angle implantation, which can be an additional benefit. FIG. 6 illustrates that inversion oxide thickness (Tₒₓ_{_}ᵢₙᵥ) does not shift much using the high-angle implantation.

Among other things, the use of high-angle implantation for source/drain regions allows fine tuning of the threshold voltage within a wider process window to achieve a target device performance. Moreover, this can be achieved without compromising device performance and gate oxide integrity and without requiring an extra masking operation. In particular embodiments, the high-angle implantation could denote a high P dose n-type source/drain (NSD) implant, which can be used to fabricate n-type devices.

Although FIGS. 2 through 6 illustrate charts showing examples of characteristics associated with tuning a threshold voltage of a semiconductor device, various changes may be made to FIGS. 2 through 6. For example, these figures illustrate example characteristics only. The characteristics of any particular semiconductor device can vary based on a number of factors, such as its design and fabrication.

FIG. 7 illustrates an example method 700 for fabricating a semiconductor device according to this disclosure. For ease of explanation, the method 700 is described with respect to the semiconductor device 100 of FIG. 1. However, the method 700 could be used with any other suitable semiconductor device.

As shown in FIG. 7, a gate dielectric layer is formed over a semiconductor substrate at step 702, a conductive layer is formed over the gate dielectric layer at step 704, and the gate dielectric layer and the conductive layer are etched to form a gate electrical contact at step 706. This could include, for example, depositing an SiON, SiO₂, or other dielectric layer over the substrate 102. This could also include depositing a polysilicon or other conductive layer over the dielectric layer. This could further include performing a pattern and etch process to form the gate contact 114 and the gate dielectric 116.

A high-angle implant of the substrate is performed to form one or more source/drain regions at step 708. This could include, for example, performing an implant of p-type or n-type dopant(s) at an angle of about 45°, although other angles could also be used. The specific angle to be used could be determined in any suitable manner, such as based on the desired amount of threshold voltage shift. During this time, various portions of the structure could be masked to avoid implanting the dopant(s) into undesired areas. An implant of the gate contact could also be performed at step 710. The implant here could represent the same implant being used to form the source and drain regions or a different implant.

Source and drain electrical contacts are formed over the substrate at step 712. This could include, for example, depositing a layer of one or more conductive materials and etching the conductive material(s) to form the source contact 110 and the drain contact 112. The formation of a semiconductor device is completed at step 714. This could include, for example, forming electrical connections to the contacts 110-114, encapsulating the structure, or performing other operations.

Although FIG. 7 illustrates one example of a method 700 for fabricating a semiconductor device, various changes may be made to FIG. 7. For example, while shown as a series of steps, various steps in FIG. 7 may overlap, occur in parallel, occur in a different order, or occur multiple times.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in this patent document should not be read as implying that any particular element, step, or function is an essential or critical element that must be included in the claim scope. Also, none of the claims is intended to invoke 35 U.S.C. §112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” “processing device,” or “controller” within a claim is understood and intended to refer to structures known to those skilled in the relevant art, as further modified or enhanced by the features of the claims themselves, and is not intended to invoke 35 U.S.C. §112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method for tuning a threshold voltage of a semiconductor device, the method comprising:
implanting at least one dopant in a semiconductor substrate at an angle to form at least one of a source region and a drain region of a transistor, the angle being oblique to a surface of the substrate;
wherein implanting the at least one dopant at the angle alters a flat-band voltage of the transistor and shifts the threshold voltage of the transistor.

2. The method of claim 1, further comprising:
implanting at least one additional dopant in a gate electrical contact of the transistor.

3. The method of claim 1, wherein implanting the at least one dopant comprises implanting the at least one dopant in at least one of the source region and the drain region and in a gate electrical contact of the transistor.

4. The method of claim 1, wherein the angle is about 45° as measured from the surface of the substrate.

5. The method of claim 1, wherein implanting the at least one dopant comprises implanting the at least one dopant to form both the source region and the drain region of the transistor.

6. The method of claim 1, wherein the at least one dopant comprises an n-type dopant.

7. The method of claim 1, wherein implanting the at least one dopant at the oblique angle changes an electrostatic potential of a gate electrical contact of the transistor compared to implanting the at least one dopant at a non-oblique angle, the change in the electrostatic potential of the gate electrical contact shifting the threshold voltage of the transistor.

8. A method of forming a transistor, the method comprising:
obtaining a semiconductor substrate;
forming a gate structure over the semiconductor substrate, the gate structure comprising a gate electrical contact and a gate dielectric layer disposed between the semiconductor substrate and the gate electrical contact; and
implanting at least one dopant in the semiconductor substrate at an angle to form at least one of a source region and a drain region of the transistor, the angle being oblique to a surface of the semiconductor substrate.

9. The method of claim 8, further comprising:
identifying a desired threshold voltage of the transistor; and
selecting the angle to alter a flat-band voltage of the transistor and shift the threshold voltage of the transistor to the desired threshold voltage.

10. The method of claim 8, further comprising:
implanting at least one additional dopant in the gate electrical contact of the transistor.

11. The method of claim 8, wherein implanting the at least one dopant comprises implanting the at least one dopant in at least one of the source region and the drain region and in the gate electrical contact of the transistor.

12. The method of claim 8, wherein the angle is about 45° as measured from the surface of the substrate.

13. The method of claim 8, wherein implanting the at least one dopant comprises implanting the at least one dopant to form both the source region and the drain region of the transistor.

14. The method of claim 8, wherein the at least one dopant comprises an n-type dopant.

15. The method of claim 8, wherein implanting the at least one dopant at the oblique angle changes an electrostatic potential of the gate electrical contact of the transistor compared to implanting the at least one dopant at a non-oblique angle, the change in the electrostatic potential of the gate electrical contact shifting the threshold voltage of the transistor.

16. A transistor comprising:
a semiconductor substrate;
a gate structure over the semiconductor substrate, the gate structure comprising a gate electrical contact and a gate dielectric layer disposed between the semiconductor substrate and the gate electrical contact; and
a source region and a drain region in the semiconductor substrate, at least one of the source and drain regions comprising at least one dopant implanted in the semiconductor substrate at an angle that is oblique to a surface of the semiconductor substrate.

17. The transistor of claim 16, wherein:
the gate electrical contact comprises polysilicon; and
the gate dielectric layer comprises an oxide.

18. The transistor of claim 16, wherein the gate electrical contact comprises at least one additional dopant.

19. The transistor of claim 16, wherein the gate electrical contact comprises the at least one dopant.

20. The transistor of claim 16, wherein the at least one dopant implanted at the oblique angle changes an electrostatic potential of the gate electrical contact of the transistor compared to implanting the at least one dopant at a non-oblique angle, the change in the electrostatic potential of the gate electrical contact shifting the threshold voltage of the transistor.
